(19) United States
(12) Patent Application Publication
(10) Pub. No.: US 2025/0337621 A1
(43) Pub. Date: Oct. 30, 2025

(54) EQUALIZER CIRCUIT

(71) Applicants: ANALOGIX (CHINA) SEMICONDUCTOR, INC., Beijing (CN); ANALOGIX INTERNATIONAL LLC, Wilmington, DE (US)

(72) Inventors: Jiawei JIN, Beijing (CN); Zhongyuan HOU, Beijing (CN); Liang XUE, Beijing (CN)

(21) Appl. No.: 19/199,047

(22) Filed: May 5, 2025

Related U.S. Application Data
(63) Continuation of application No. PCT/CN2023/086284, filed on Apr. 4, 2023.

(30) Foreign Application Priority Data
Feb. 7, 2023 (CN) 202310115480.5

(51) Int. Cl. H04L 25/03; H03G 3/30

(52) U.S. Cl. CPC H04L 25/03878; H03G 3/3036

(57) ABSTRACT

Disclosed in the disclosure is an equalizer circuit. The equalizer circuit includes a current source component, a resistance-capacitance (RC) network, and a differential transistor pair, where the current source component is electrically connected to the RC network, and the RC network is electrically connected to the differential transistor pair; and the equalizer circuit further includes an adjustable active inductor component electrically connected to a first transistor and a second transistor of the differential transistor pair separately; and a control component electrically connected to the current source component, the RC network, and the adjustable active inductor component separately and configured to change frequencies of a dominant pole and a non-dominant pole of the equalizer circuit by adjusting performance parameters of the current source component, the RC network, and the adjustable active inductor component.

### CROSS-REFERENCE TO RELATED APPLICATION

The disclosure is a continuation of PCT Application No. PCT/CN2023/086284 file Apr. 4, 2023, which claims the priority of Chinese Patent Application No. 202310115480.5, filed with the China National Intellectual Property Administration on Feb. 7, 2023 and entitled “Equalizer Circuit”, both of which are incorporated in their entirety herein by reference.

### TECHNICAL FIELD

The disclosure relates to the technical field of data transmission, and in particular to an equalizer circuit.

### BACKGROUND

An equalizer (EQ), an essential component of a chip receiving terminal, is used to compensate channel attenuation of a signal. The channel attenuation to be compensated by the EQ varies with different interface protocols and different rates. It is common practice to set a gain boost of the EQ to be adjustable, for example, within 0 dB-15 dB with a step size of 1 dB or so, so as to solve the problem of difference in attenuation between a long channel and a short channel.

A maximum bandwidth in data transmission is compensated in the related art. Accordingly, a frequency point where the EQ can offer a maximum gain boost is positioned at the maximum bandwidth. For example, an EQ primarily serves as a channel attenuation compensation component in a re-driver chip (a signal retiming chip). Assuming that the chip supports both universal serial bus (USB) 4.0 and USB 3.2, if an EQ circuit is designed at a rate of USB 4.0, frequency peaking is designed as 10 GHz, and a maximum gain boost appears at 15 dB. Moreover, in consideration of the long channel and the short channel, the gain boost is designed to be adjustable within 0 dB-15 dB. Consequently, a gain boost at a Nyquist frequency point (5 GHz) of USB 3.2 is far less than 15 dB, leading to limited application to serious channel attenuation of USB 3.2. Assuming that frequency peaking is designed as 5 GHz, and a maximum gain boost is also designed to appear at 15 dB, a gain boost at 10 GHz is much greater than 15 dB. Consequently, excessive power consumption is caused, a guarantee that the gain boost is adjustable within 0 dB-15 dB cannot be given, and especially a minimum gain boost cannot be covered.

In view of the problem that not all gain boosts of frequency peaking are adjustable within 0 dB-15 dB since the channel attenuation to be compensated by the EQ varies with different protocols and different rates in the related art, no effective solution has been provided yet.

### SUMMARY

The embodiments of the disclosure provide an equalizer circuit. The equalizer circuit includes a current source component, a resistance-capacitance (RC) network, and a differential transistor pair, where the current source component is electrically connected to the RC network, and the RC network is electrically connected to the differential transistor pair; and the equalizer circuit further includes: an adjustable active inductor component electrically connected to a first transistor and a second transistor of the differential transistor pair separately; and a control component electrically connected to the current source component, the RC network, and the adjustable active inductor component separately and configured to change frequencies of a dominant pole and a non-dominant pole of the equalizer circuit by adjusting performance parameters of the current source component, the RC network, and the adjustable active inductor component.

In some embodiments, the adjustable active inductor component includes a first adjustable current source, a first adjustable resistor, a first adjustable capacitor, and a first transistor; where the RC network is electrically connected to the first adjustable current source, the first transistor, and the first adjustable resistor separately; a first end of the first adjustable resistor is electrically connected to the RC network, and a second end of the first adjustable resistor is electrically connected to a gate of the first transistor and the first adjustable capacitor separately.

In some embodiments, the current source component includes a second current source and a third current source, the differential transistor pair includes a second transistor and a third transistor, and the RC network includes a second adjustable resistor, a second adjustable capacitor component, and a third adjustable capacitor component; where the second adjustable resistor is connected to the second adjustable capacitor component in parallel, the second current source is electrically connected to a first parallel node of the second adjustable resistor and the second adjustable capacitor component, and the third current source is electrically connected to a second parallel node of the second adjustable resistor and the second adjustable capacitor component; and the first parallel node is electrically connected to a first end of the third adjustable capacitor component through the second transistor, and the second parallel node is electrically connected to a second end of the third adjustable capacitor component through the third transistor.

In some embodiments, the control component includes a decoder configured to receive an encoded signal and decode the encoded signal according to a decoder truth table to obtain a logic control signal; and a controller electrically connected to the decoder, the current source component, the RC network and the adjustable active inductor component separately and configured to adjust the performance parameters of the current source component, the RC network, and the adjustable active inductor component according to the logic control signal.

In some embodiments, the decoder is configured to receive a first encoded signal and decode the first encoded signal according to a first decoder truth table to obtain a first logic control signal; where the first logic control signal is configured to indicate the following control information to the controller: current values of the second current source and the third current source are increased, a capacitance value of the first adjustable capacitor is decreased, and a resistance value of the first adjustable resistor is decreased, so that a current value of the first adjustable current source satisfies a first preset range; and the controller is configured to adjust the second current source, the third current source, the first adjustable capacitor, the first adjustable resistor, and the first adjustable current source according to the first logic control signal, so as to reduce the frequencies of the dominant pole and the non-dominant pole of the equalizer circuit.

In some embodiments, the decoder is configured to receive a second encoded signal and decode the second encoded signal according to a second decoder truth table to obtain a second logic control signal; where the second logic control signal is configured to indicate the following control information to the controller: current values of the second current source and the third current source are decreased, a capacitance value of the first adjustable capacitor is increased, and a resistance value of the first adjustable resistor is increased, so that a current value of the first adjustable current source satisfies a second preset range; and the controller is configured to adjust the second current source, the third current source, the first adjustable capacitor, the first adjustable resistor, and the first adjustable current source according to the second logic control signal, so as to increase the frequencies of the dominant pole and the non-dominant pole of the equalizer circuit.

In some embodiments, the decoder is configured to receive the second encoded signal and a third encoded signal, decode the second encoded signal according to the second decoder truth table to obtain the second logic control signal, and decode the third encoded signal according to a third decoder truth table to obtain a third logic control signal; where the third logic control signal is configured to indicate the following control information to the controller: current values of the second current source and the third current source are decreased, a capacitance value of the first adjustable capacitor is decreased, and a resistance value of the first adjustable resistor is decreased, so that a current value of the first adjustable current source satisfies a second preset range; and the controller is configured to adjust the second current source, the third current source, the first adjustable capacitor, the first adjustable resistor, and the first adjustable current source according to the second logic control signal and the third logic control signal in sequence.

In some embodiments, the second adjustable capacitor component includes a plurality of first capacitor branches connected in parallel, and each first capacitor branch includes a first capacitor and a first switch connected in series; and the third adjustable capacitor component includes a plurality of second capacitor branches connected in parallel, and each second capacitor branch includes a second capacitor and a second switch connected in series.

In some embodiments, the controller is further configured to control the first switch and the second switch to be turned on or off according to the logic control signal.

### BRIEF DESCRIPTION OF THE DRAWINGS

The accompanying drawings are used to provide further understanding of the disclosure as a constitute part of the disclosure. The illustrative examples of the disclosure and their description serve to explain the disclosure, instead of limiting the disclosure improperly. In the accompanying drawings:

FIG. 1 is a schematic diagram of an equalizer circuit according to an example of the disclosure;

FIG. 2 is a schematic diagram of a dynamically-adjustable active inductor in an equalizer circuit according to an example of the disclosure;

FIG. 3 is a schematic diagram of a zero pole distribution of a dynamically-adjustable active inductor according to an example of the disclosure;

FIG. 4 is a schematic diagram of a decoder truth table for adjusting frequency peaking of an equalizer circuit to move to a higher frequency according to an example of the disclosure;

FIG. 5 is a schematic diagram of a relation curve between a frequency and a gain boost in a process of adjusting frequency peaking of an equalizer circuit to move to a higher frequency according to an example of the disclosure;

FIG. 6 is a schematic diagram of a decoder truth table in a process of adjusting frequency peaking of an equalizer circuit to move to a lower frequency according to an example of the disclosure;

FIG. 7 is a schematic diagram of a relation curve between a frequency and a gain boost in a process of adjusting frequency peaking of an equalizer circuit to move to a lower frequency according to an example of the disclosure;

FIG. 8 is a schematic diagram of another decoder truth table in a process of adjusting frequency peaking of an equalizer circuit to move to a lower frequency according to an example of the disclosure; and

FIG. 9 is a schematic diagram of another relation curve between a frequency and a gain boost in a process of adjusting frequency peaking of an equalizer circuit to move to a lower frequency according to an example of the disclosure.

### DETAILED DESCRIPTION OF THE EMBODIMENTS

It should be noted that examples of the disclosure and features in the examples can be mutually combined without conflicts. The disclosure will be described in detail below in conjunction with the accompanying drawings and the examples.

In order to enable those skilled in the art to better understand solutions of the disclosure, the technical solutions in the examples of the disclosure will be clearly and comprehensively described below in conjunction with the accompanying drawings in the examples of the disclosure. Apparently, the examples described are merely some examples rather than all examples of the disclosure. Based on the examples of the disclosure, all other examples derived by those of ordinary skill in the art without making creative efforts fall within the scope of protection of the disclosure.

It should be noted that the terms “first”, “second”, etc. in the description and claims of the disclosure and the above accompanying drawings are used to distinguish between similar objects, instead of necessarily describing a particular sequence or a successive order. It should be understood that data used in this way can be interchanged where appropriate, so as to facilitate the examples of the disclosure described herein. In addition, the terms “comprise”, “include”, “have”, and their any variations are intended to cover non-exclusive inclusion. For example, processes, methods, systems, products, or devices encompassing a series of steps or units can include other steps or units, which are not explicitly listed or are inherent to these processes, methods, products, or devices, without being limited to those steps or units explicitly listed.

For the sake of description, some nouns or terms involved in the examples of the disclosure are described below:
Equalizer: short for EQ.
Decoder: short for Dec.
Gain boost: a boost in gain.
Frequency peaking: a frequency peak.

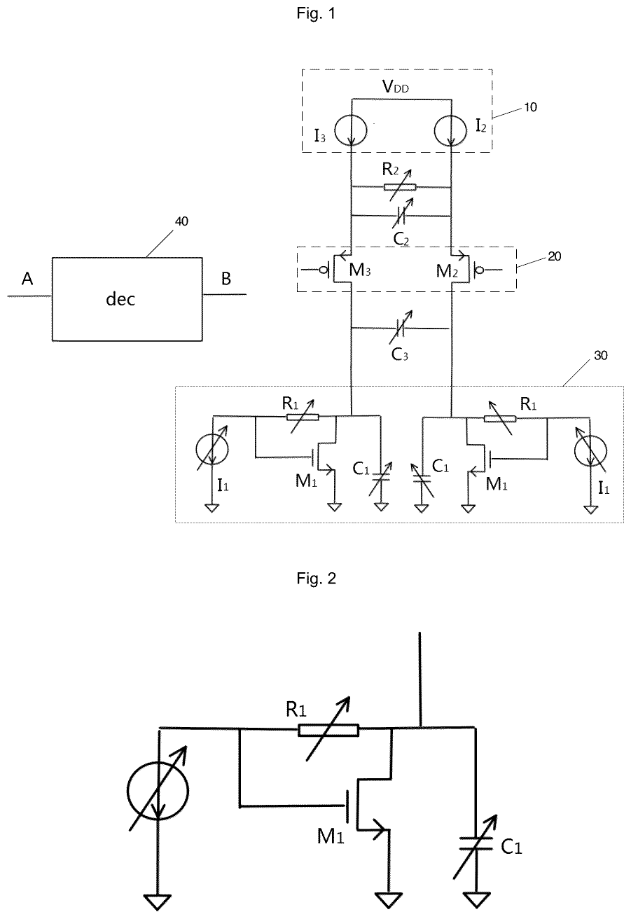

An equalizer circuit is provided according to an example of the disclosure. As shown in FIG. 1, the equalizer circuit includes: a current source component 10, a resistance-capacitance (RC) network, and a differential transistor pair 20, where the current source component is electrically connected to the RC network, and the RC network is electrically connected to the differential transistor pair; and the equalizer circuit further includes:

an adjustable active inductor component 30 electrically connected to a first transistor and a second transistor of the differential transistor pair 20 separately; and
a control component 40 electrically connected to the current source component 10, the RC network, and the adjustable active inductor component 30 separately (a connection relation is not shown in FIG. 1), and configured to change frequencies of a dominant pole and a non-dominant pole of the equalizer circuit by adjusting performance parameters of the current source component 10, the RC network, and the adjustable active inductor component 30.

According to the example, since the above control component is electrically connected to the current source component, the RC network, and the adjustable active inductor component separately, the frequencies of the dominant pole and the non-dominant pole of the equalizer circuit may be changed by adjusting the performance parameters of the current source component, the RC network, and the adjustable active inductor component. Accordingly, compensation curves for different frequency peaking can be obtained, so as to well realize a channel compensation under different protocols and different rates compatibly. Gain boosts of a plurality of pieces of frequency peaking are adjustable within 0 dB-15 dB. The problem that not all gain boosts of frequency peaking are adjustable within 0 dB-15 dB since channel attenuation to be compensated by an equalizer (EQ) varies with different protocols and different rates in the related art is solved.

In some alternative embodiments, in the equalizer circuit according to the example, the adjustable active inductor component includes a first adjustable current source, a first adjustable resistor, a first adjustable capacitor, and a first transistor; where the RC network is electrically connected to the first adjustable current source, the first transistor, and the first adjustable resistor separately; a first end of the first adjustable resistor is electrically connected to the RC network, and a second end of the first adjustable resistor is electrically connected to a gate of the first transistor and the first adjustable capacitor separately.

In the above alternative embodiment, the adjustable active inductor component is configured to contribute to a zero pole of the equalizer circuit. The first adjustable current source functions to shunt a current of the first transistor and adjust transconductance of the first transistor.

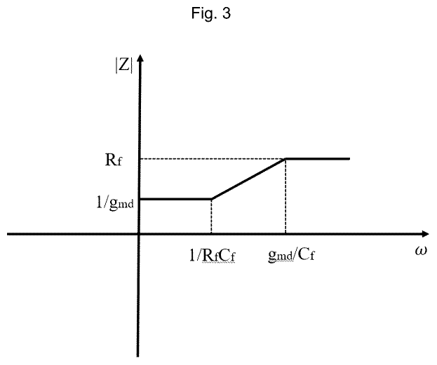

Illustratively, as shown in FIGS. 1 and 2, the adjustable active inductor component 30 is composed of a first adjustable current source I₁, a first adjustable resistor R₁, a first adjustable capacitor C₁, and a first transistor M₁. The zero pole contributed by the adjustable active inductor component is as shown in FIG. 3. Specifically, R_{f} denotes a resistance value of the first adjustable resistor R₁, C_{f} denotes a capacitance value of the first adjustable capacitor C₁, and g_{md} denotes the transconductance of the first transistor M₁. It can be visually seen from FIG. 3 that a higher frequency has a greater amplitude than a lower frequency, and thus functions as a zero point.

In some alternative embodiments, in the equalizer circuit according to the example, the current source component includes a second current source and a third current source, the differential transistor pair includes a second transistor and a third transistor, and the RC network includes a second adjustable resistor, a second adjustable capacitor component, and a third adjustable capacitor component; where the second adjustable resistor is connected to the second adjustable capacitor component in parallel, the second current source is electrically connected to a first parallel node of the second adjustable resistor and the second adjustable capacitor component, and the third current source is electrically connected to a second parallel node of the second adjustable resistor and the second adjustable capacitor component; and the first parallel node is electrically connected to a first end of the third adjustable capacitor component through the second transistor, and the second parallel node is electrically connected to a second end of the third adjustable capacitor component through the third transistor.

Illustratively, as shown in FIG. 1, the above current source component 10 includes a second current source I₂ and a third current source I₃, where the two current sources provide the same static current. The above differential transistor pair 20 includes a second transistor M₂ and a third transistor M₃. The above RC network includes a second adjustable resistor R₂, a second adjustable capacitor component C₂, and a third adjustable capacitor component C₃ connected in parallel.

Specifically, the dominant pole and the non-dominant pole of the equalizer may be made into dynamically-adjustable poles, so as to make the frequency peaking adjustable, in order to solve the problem that the channel attenuation to be compensated by the equalizer (EQ) varies with different protocols and different rates, and make the gain boost of each frequency peaking adjustable within 0 dB-15 dB.

With the equalizer circuit shown in FIG. 1 as an example, positions of the zero point, the dominant pole, and the non-dominant pole may be changed by adjusting the adjustable resistor, the adjustable capacitor, and the adjustable resistor. Accordingly, the frequency response of the equalizer is changed to compensate channel attenuation of a signal. Specifically, a transfer function of the above equalizer circuit has an expression

$$H ( s ) = \frac{{g}_{m}}{2 {C}_{d}} \cdot \frac{s + \frac{1}{{R}_{s} {c}_{s}}}{( s + \frac{1 + {g}_{m {R}_{s} / 2}}{{R}_{s} {C}_{s}} ) ( s + \frac{1}{{R}_{d} \times 2 \times {C}_{d}} )} .$$

gₘ denotes transconductance of the second transistor M₂, C_{d} denotes a capacitance value of the third adjustable capacitor component C₃, Rₛ denotes a resistance value of the second adjustable resistor R₂, Cₛ denotes a capacitance value of the second adjustable capacitor component C₂, and R_{d} denotes a resistance value of the adjustable active inductor component.

The above transfer function is utilized to obtain an expression of the zero point of the equalizer circuit as

$${ω}_{z} = \frac{1}{{R}_{s} {C}_{s}} ,$$

an expression of the dominant pole as

$${ω}_{p 1} = \frac{1 + {g}_{m {R}_{s} / 2}}{{R}_{s} {C}_{s}} ,$$

and an expression of the non-dominant pole as

$${ω}_{p 2} = \frac{1}{2 \times {R}_{d} {C}_{d}} .$$

The resistance value R_{d} is determined through the first adjustable current source I₁, the first adjustable resistor R₁, the first adjustable capacitor C₁, and the first transistor M₁ in the adjustable active inductor component. Accordingly, the dominant pole and the non-dominant pole of the equalizer may be adjusted by adjusting the performance parameters of the current source component, the RC network, and the adjustable active inductor component.

In the equalizer circuit according to the example, the control component may include a decoder and a controller. The decoder is configured to receive an encoded signal and decode the encoded signal according to a decoder truth table to obtain a logic control signal. The controller is electrically connected to the decoder, the current source component, the RC network, and the adjustable active inductor component separately and configured to adjust the performance parameters of the current source component, the RC network, and the adjustable active inductor component according to the logic control signal.

Specifically, the performance parameters of the current source component, the RC network, and the adjustable active inductor component are configured through the decoder. When higher frequency peaking is designed, the dominant pole ωₚ₁ and the non-dominant pole ωₚ₂ are pushed to a higher frequency. When lower frequency peaking is designed, the ωₚ₁ and the ωₚ₂ are pushed to a lower frequency. Accordingly, the frequencies of the two poles are changed, and the compensation under different rates and different channels is realized. Moreover, power consumption of data transmission at a low rate can also be reduced.

Illustratively, the first adjustable current source I₁ is set to have a current value I_{f}, the second adjustable current source I₂ and the third adjustable current source I₃ are set to have a current value Iₛ, the first adjustable resistor R₁ is set to have a resistance value R_{f}, the first adjustable capacitor C₁ is set to have a capacitance value C_{f}, the second adjustable capacitor C₂ is set to have a capacitance value Cₛ, and the third adjustable capacitor C₃ is set to have a capacitance value C_{d}. Iₛ, C_{d}, Cₛ, R_{f}, C_{f}, and I_{f} are configured through the decoder, so that the dominant pole ωₚ₁ and the non-dominant pole ωₚ₂ of the equalizer are adjustable. The control logic of the controller may be realized through the decoder.

Further, in order to make the capacitance values Cₛ and C_{d} adjustable, the second adjustable capacitor component C₂ may include a plurality of first capacitor branches connected in parallel, and each first capacitor branch includes a first capacitor and a first switch connected in series. Whether first capacitors on the plurality of first capacitor branches above are in a working state is determined through the decoder truth table, so as to determine whether the corresponding capacitors are connected into internal nodes of the equalizer circuit through the first switches.

Accordingly, the controller controls the first switch above to be turned on or off according to the logic control signal, thereby adjusting the capacitance value Cₛ of the second adjustable capacitor component C₂. The third adjustable capacitor component C₃ may also include a plurality of second capacitor branches connected in parallel, and each second capacitor branch includes a second capacitor and a second switch connected in series. Whether second capacitors on the plurality of second capacitor branches above are in a working state is determined through the decoder truth table, so as to determine whether the corresponding capacitors are connected into internal nodes of the equalizer circuit through the second switches. Accordingly, the controller controls the second switch above to be turned on or off according to the logic control signal, thereby adjusting the capacitance value C_{d} of the third adjustable capacitor component C₃. Whether the first capacitor and the second capacitor above are in the working state is indicated through 0 or 1 in the truth table.

In order to realize higher frequency peaking, in some alternative embodiments, the decoder is configured to receive a first encoded signal and decode the first encoded signal according to a first decoder truth table to obtain a first logic control signal; where the first logic control signal is configured to indicate the following control information to the controller: the current values of the second current source and the third current source are increased, the capacitance value of the first adjustable capacitor is decreased, and the resistance value of the first adjustable resistor is decreased, so that the current value of the first adjustable current source satisfies a first preset range. The controller is configured to adjust the second current source, the third current source, the first adjustable capacitor, the first adjustable resistor, and the first adjustable current source according to the first logic control signal. Accordingly, the frequencies of the dominant pole and the non-dominant pole of the equalizer circuit are reduced.

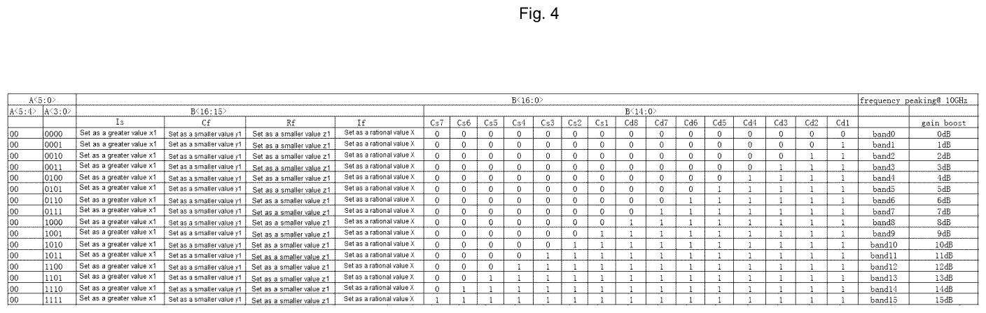

Illustratively, the first decoder truth table above is as shown in FIG. 4. When first capacitance Cₛ₁-Cₛ₇ is set as 1 (indicating true) separately, it means that the corresponding capacitors are connected into the internal nodes of the equalizer circuit through first switches turned on. When first capacitance Cₛ₁-Cₛ₇ is set as 0 (indicating false), it means that the corresponding capacitors are not connected into the internal nodes of the equalizer circuit because the first switches are turned off. When second capacitance C_{d1}-C_{d8} equals 1, it means that the second corresponding capacitors are connected into the internal nodes of the equalizer circuit through second switches turned on. When second capacitance C_{d1}-C_{d8} equals 0, it means that the second corresponding capacitors are not connected into the internal nodes of the equalizer circuit because the second switches are turned off. Iₛ denotes a current value of a current source configured to provide a current for the equalizer (EQ). Rₛ is configured to adjust a direct current gain (DC gain) of the circuit. The decoder has an input A<5:0> and an output B<16:0>. Binary operators of A<3:0> denote true or false values of the first capacitance Cₛ₁-Cₛ₇ in the table. The binary number in A<3:0> varies with the true or false values of the first capacitance Cₛ₁-Cₛ₇ in the table. A<5:4> maintains an input value as 00 all the time.

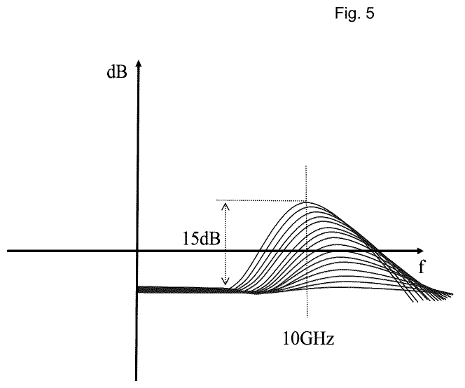

Specifically, when higher frequency peaking is designed, as shown in FIG. 4, Iₛ may be set as a greater value x1, C_{f} may be set as a smaller value y1, and R_{f} may be set as a smaller value z1. Therefore, Iₛ is increased, R_{f} and C_{f} are decreased, and I_{f} is set as a rational value X. The gain boost of the equalizer may be realized by adjusting Cₛ and C_{d}, so that a set of 16 curve bands with an adjustable gain boost, as shown in FIG. 5, where the frequency peaking is 10 GHz, and the gain boost of the frequency peaking is adjustable within 0 dB-15 dB.

In order to realize lower frequency peaking, in some alternative embodiments, the decoder is configured to receive a second encoded signal and decode the second encoded signal according to a second decoder truth table to obtain a second logic control signal; where the second logic control signal is configured to indicate the following control information to the controller: the current values of the second current source and the third current source are decreased, the capacitance value of the first adjustable capacitor is increased, and the resistance value of the first adjustable resistor is increased, so that a current value of the first adjustable current source satisfies a second preset range. The controller is configured to adjust the second current source, the third current source, the first adjustable capacitor, the first adjustable resistor, and the first adjustable current source according to the second logic control signal, so as to increase the frequencies of the dominant pole and the non-dominant pole of the equalizer circuit.

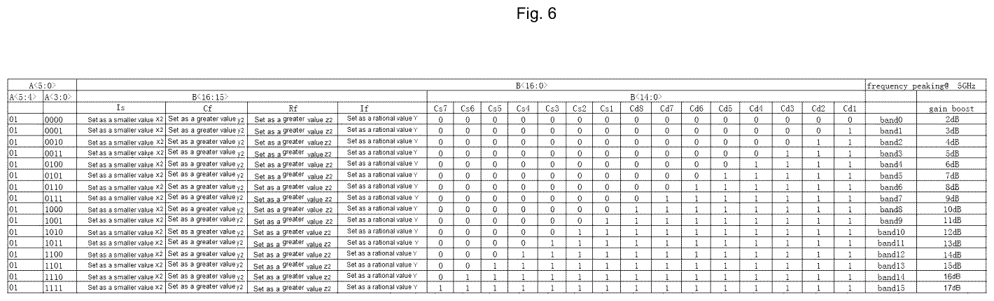

Illustratively, the second decoder truth table above is as shown in FIG. 6. When first capacitance Cₛ₁-Cₛ₇ is set as 1 (indicating true) separately, it means that the corresponding capacitors are connected into the internal nodes of the equalizer circuit through first switches turned on. When first capacitance Cₛ₁-Cₛ₇ is set as 0 (indicating false), it means that the corresponding capacitors are not connected into the internal nodes of the equalizer circuit because the first switches are turned off. When second capacitance C_{d1}-C_{d8} equals 1, it means that the second corresponding capacitors are connected into the internal nodes of the equalizer circuit through second switches turned on. When second capacitance C_{d1}-C_{d8} equals 0, it means that the second corresponding capacitors are not connected into the internal nodes of the equalizer circuit because the second switches are turned off. Iₛ denotes a current value of a current source configured to provide a current for the equalizer (EQ). Rₛ is configured to adjust a direct current gain (DC gain) of the circuit. The decoder has an input A<5:0> and an output B<16:0>. Binary operators of A<3:0> denote true or false values of the first capacitance Cₛ₁-Cₛ₇ in the table. The binary number in A<3:0> varies with the true or false values of the first capacitance Cₛ₁-Cₛ₇ in the table. A<5:4> maintains an input value as 01 all the time.

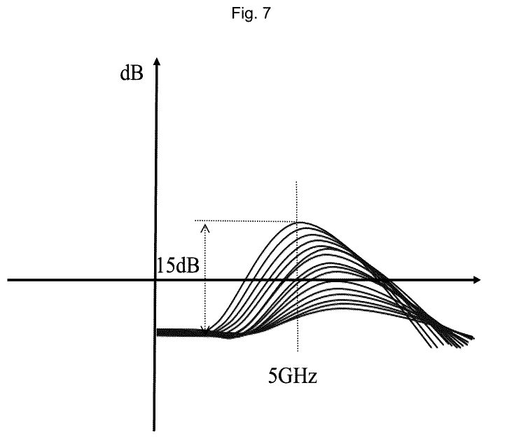

Specifically, in order to move the frequency peaking to a low frequency, as shown in FIG. 6, Iₛ may be set as a smaller value x₂. Therefore, a current of Iₛ is decreased firstly, and the dominant pole ωₚ₁ is moved to a lower frequency. Moreover, C_{f} is set as a greater value y₂, and R_{f} is set as a greater value z₂. Therefore, R_{f} and C_{f} are increased, and the non-dominant pole ωₚ₂ is also moved to a lower frequency. I_{f} is set as a rational value Y. Similarly, the gain boost of the equalizer may be realized by adjusting Cₛ and C_{d}, so that a set of 16 curve bands with an adjustable gain boost is obtained, as shown in FIG. 7, where the frequency peaking is 5 GHz, and the gain boost of the frequency peaking is adjustable within 0 dB-15 dB.

A relation curve between a frequency and a gain boost is shifted upwards as a whole on the basis of an increase of C_{f} and R_{f}. In this case, in order to realize lower frequency peaking, in some other alternative embodiments, the decoder is configured to receive the second encoded signal and a third encoded signal, decode the second encoded signal according to the second decoder truth table to obtain the second logic control signal, and decode the third encoded signal according to a third decoder truth table to obtain a third logic control signal; where the third logic control signal is configured to indicate the following control information to the controller: the current values of the second current source and the third current source are decreased, the capacitance value of the first adjustable capacitor is decreased, and the resistance value of the first adjustable resistor is decreased, so that a current value of the first adjustable current source satisfies a second preset range. The controller is configured to adjust the second current source, the third current source, the first adjustable capacitor, the first adjustable resistor, and the first adjustable current source according to the second logic control signal and the third logic control signal in sequence.

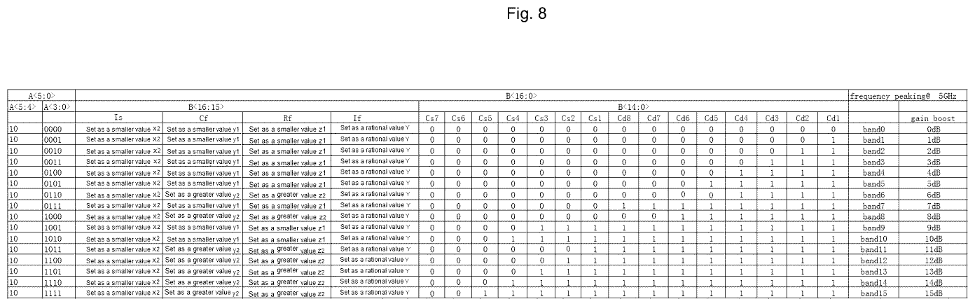

Illustratively, the third decoder truth table above is as shown in FIG. 8. When first capacitance Cₛ₁-Cₛ₇ is set as 1 (indicating true) separately, it means that the corresponding capacitors are connected into the internal nodes of the equalizer circuit through first switches turned on. When first capacitance Cₛ₁-Cₛ₇ is set as 0 (indicating false), it means that the corresponding capacitors are not connected into the internal nodes of the equalizer circuit because the first switches are turned off. When second capacitance C_{d1}-C_{d8} equals 1, it means that the second corresponding capacitors are connected into the internal nodes of the equalizer circuit through second switches turned on. When second capacitance C_{d1}-C_{d8} equals 0, it means that the second corresponding capacitors are not connected into the internal nodes of the equalizer circuit because the second switches are turned off. Iₛ denotes a current value of a current source configured to provide a current for the equalizer (EQ). Rₛ is configured to adjust a direct current gain (DC gain) of the circuit. The decoder has an input A<5:0> and an output B<16:0>. Binary operators of A<3:0> denote true or false values of the first capacitance Cₛ₁-Cₛ₇ in the table. The binary number in A<3:0> varies with the true or false values of the first capacitance Cₛ₁-Cₛ₇ in the table. A<5:4> maintains an input value as 10 all the time.

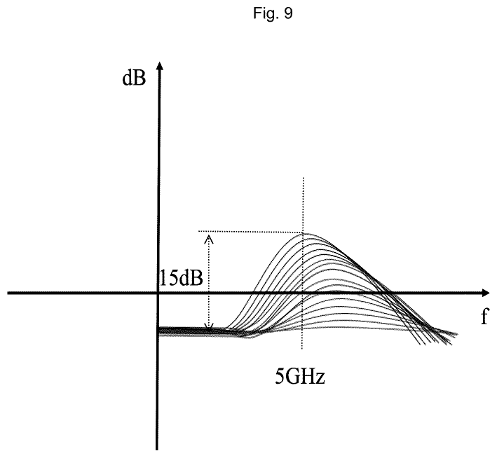

Specifically, the above embodiment may include two steps: firstly, as shown in FIG. 8, I_{f} may be adjusted to a rational value Y, and Iₛ may be set as a small value x₂, so that Iₛ is decreased; moreover, C_{f} is set as a greater value y₂, and R_{f} is set as a greater value z₂, so that R_{f} and C_{f} are increased; and then, Cₛ and C_{d} are adjusted to obtain a set of gain boost curves of 16 curve bands. Then, C_{f} is set as a smaller value y₁, and R_{f} is set as a smaller value z₁, so that R_{f} and C_{f} are decreased; and then, Cₛ and C_{d} are adjusted to obtain another set of gain boost curves of 16 curve bands. Finally, two sets of curves are superimposed together to select 16 desired gain boost curves, as shown in FIG. 9, the frequency peaking is 5 GHz, and the gain boost of the frequency peaking is adjustable within 0 dB-15 dB. The control logic is realized through the decoder, so that the gain boost of each frequency peaking is adjustable within 0 dB-15 dB.

A method for adjusting a pole frequency of an equalizer circuit is further provided according to an example of the disclosure. The method for adjusting a pole frequency of an equalizer circuit according to the example of the disclosure may be applied to the equalizer circuit according to the above example and is described below.

The method for adjusting a pole frequency according to the example includes:

A control component in the equalizer circuit receives a control signal.

The above control component adjusts performance parameters of a current source component, an RC network, and an adjustable active inductor component in the equalizer circuit according to the control signal. The controller adjusts the performance parameters of the current source component, the RC network, and the adjustable active inductor component according to the logic control signal, so as to change frequencies of a dominant pole and a non-dominant pole of the equalizer circuit.

According to the example, since the control component in the equalizer circuit is electrically connected to the current source component, the RC network, and the adjustable active inductor component separately, the frequencies of the dominant pole and the non-dominant pole of the equalizer circuit may be changed by adjusting the performance parameters of the current source component, the RC network, and the adjustable active inductor component according to a received control signal. Accordingly, compensation curves for different frequency peaking can be obtained, so as to well realize a channel compensation under different protocols and different rates compatibly. Gain boosts of a plurality of pieces of frequency peaking are adjustable within 0 dB-15 dB. The problem that not all gain boosts of frequency peaking are adjustable within 0 dB-15 dB since channel attenuation to be compensated by an equalizer (EQ) varies with different protocols and different rates in the related art is solved.

In some alternative embodiments, the above control component in the equalizer circuit includes a decoder and a controller. The control component is electrically connected to the decoder, the current source component, the RC network, and the adjustable active inductor component separately. The step that the control signal is received includes: the decoder receives an encoded signal and decode the encoded signal according to a decoder truth table to obtain the logic control signal.

In the above alternative embodiment, the decoder may decode the encoded signal according to the decoder truth table to obtain the logic control signal. Accordingly, the controller may adjust the performance parameters of the current source component, the RC network, and the adjustable active inductor component according to the logic control signal after receiving the logic control signal.

Specifically, the performance parameters of the current source component, the RC network, and the adjustable active inductor component are configured through the decoder. When higher frequency peaking is designed, the dominant pole ωₚ₁ and the non-dominant pole ωₚ₂ are pushed to a higher frequency. When lower frequency peaking is designed, the ωₚ₁ and the ωₚ₂ are pushed to a lower frequency. Accordingly, the frequencies of the two poles are changed, and the compensation under different rates and different channels is realized. Moreover, power consumption of data transmission at a low rate can also be reduced.

It should also be noted that the terms “comprise”, “include”, “encompass”, or their any other variations are intended to cover a non-exclusive inclusion. Therefore, a process, method, article, or device including a series of elements not only includes those elements, but also includes other elements that are not explicitly listed, or further includes elements inherent to such a process, method, article, or device. Without more restrictions, the elements defined by the sentence “comprise a . . . ” and “include a . . . ” do not exclude the existence of other identical elements in the process, method, article, or device including the elements.

What are described above are merely the examples of the disclosure, but are not intended to limit the disclosure. For those skilled in the art, the disclosure can have various modifications and changes. Any modifications, equivalent replacements, improvements, etc. made within the spirit and principles of the disclosure should fall within the scope of claims of the disclosure.

1. An equalizer circuit, comprising a current source component, a resistance-capacitance (RC) network, and a differential transistor pair, wherein the current source component is electrically connected to the RC network, and the RC network is electrically connected to the differential transistor pair; and the equalizer circuit further comprises:
an adjustable active inductor component electrically connected to a first transistor and a second transistor of the differential transistor pair separately; and
a control component electrically connected to the current source component, the RC network, and the adjustable active inductor component separately and configured to change frequencies of a dominant pole and a non-dominant pole of the equalizer circuit by adjusting performance parameters of the current source component, the RC network, and the adjustable active inductor component.

2. The equalizer circuit as claimed in claim 1, wherein the adjustable active inductor component comprises a first adjustable current source, a first adjustable resistor, a first adjustable capacitor, and a first transistor; wherein
the RC network is electrically connected to the first adjustable current source, the first transistor, and the first adjustable resistor separately; and a first end of the first adjustable resistor is electrically connected to the RC network, and a second end of the first adjustable resistor is electrically connected to a gate of the first transistor and the first adjustable capacitor separately.

3. The equalizer circuit as claimed in claim 2, wherein the current source component comprises a second current source and a third current source; the differential transistor pair comprises a second transistor and a third transistor; and the RC network comprises a second adjustable resistor, a second adjustable capacitor component, and a third adjustable capacitor component; wherein
the second adjustable resistor is connected to the second adjustable capacitor component in parallel, the second current source is electrically connected to a first parallel node of the second adjustable resistor and the second adjustable capacitor component, and the third current source is electrically connected to a second parallel node of the second adjustable resistor and the second adjustable capacitor component; and the first parallel node is electrically connected to a first end of the third adjustable capacitor component through the second transistor, and the second parallel node is electrically connected to a second end of the third adjustable capacitor component through the third transistor.

4. The equalizer circuit as claimed in claim 3, wherein the control component comprises:
a decoder configured to receive an encoded signal and decode the encoded signal according to a decoder truth table to obtain a logic control signal; and
a controller electrically connected to the decoder, the current source component, the RC network, and the adjustable active inductor component separately and configured to adjust the performance parameters of the current source component, the RC network, and the adjustable active inductor component according to the logic control signal.

5. The equalizer circuit as claimed in claim 4, wherein
the decoder is configured to receive a first encoded signal and decode the first encoded signal according to a first decoder truth table to obtain a first logic control signal; wherein the first logic control signal is configured to indicate the following control information to the controller: increasing current values of the second current source and the third current source, decreasing a capacitance value of the first adjustable capacitor, and decreasing a resistance value of the first adjustable resistor, so that a current value of the first adjustable current source satisfies a first preset range; and
the controller is configured to adjust the second current source, the third current source, the first adjustable capacitor, the first adjustable resistor, and the first adjustable current source according to the first logic control signal, so as to reduce the frequencies of the dominant pole and the non-dominant pole of the equalizer circuit.

6. The equalizer circuit as claimed in claim 4, wherein
the decoder is configured to receive a second encoded signal and decode the second encoded signal according to a second decoder truth table to obtain a second logic control signal; wherein the second logic control signal is configured to indicate the following control information to the controller: decreasing current values of the second current source and the third current source, increasing a capacitance value of the first adjustable capacitor, and increasing a resistance value of the first adjustable resistor, so that a current value of the first adjustable current source satisfies a second preset range; and
the controller is configured to adjust the second current source, the third current source, the first adjustable capacitor, the first adjustable resistor, and the first adjustable current source according to the second logic control signal, so as to increase the frequencies of the dominant pole and the non-dominant pole of the equalizer circuit.

7. The equalizer circuit as claimed in claim 6, wherein
the decoder is configured to receive the second encoded signal and a third encoded signal, decode the second encoded signal according to the second decoder truth table to obtain the second logic control signal, and decode the third encoded signal according to a third decoder truth table to obtain a third logic control signal; wherein the third logic control signal is configured to indicate the following control information to the controller: decreasing current values of the second current source and the third current source, decreasing a capacitance value of the first adjustable capacitor, and decreasing a resistance value of the first adjustable resistor, so that a current value of the first adjustable current source satisfies a second preset range; and
the controller is configured to adjust the second current source, the third current source, the first adjustable capacitor, the first adjustable resistor, and the first adjustable current source according to the second logic control signal and the third logic control signal in sequence.

8. The equalizer circuit as claimed in claim 4, wherein
the second adjustable capacitor component comprises a plurality of first capacitor branches connected in parallel, and each first capacitor branch comprises a first capacitor and a first switch connected in series; and
the third adjustable capacitor component comprises a plurality of second capacitor branches connected in parallel, and each second capacitor branch comprises a second capacitor and a second switch connected in series.

9. The equalizer circuit as claimed in claim 8, wherein the controller is further configured to control the first switch and the second switch to be turned on or off according to the logic control signal.
